(19) United States
(12) Patent Application Publication
(10) Pub. No.: US 2015/0022496 A1
(43) Pub. Date: Jan. 22, 2015

(54) TRANSPARENT CONDUCTIVE FILM HAVING EXCELLENT ELECTRICAL CHARACTERISTICS AND TOUCH PANEL USING THE SAME

(71) Applicant: LG Hausys, Ltd., Seoul (KR)

(72) Inventors: Kyung Taek Kim, Bucheon-si (KR); In Sook Kim, Daejeon (KR); Jung Cho, Seoul (KR); Keun Jung, Gwacheon-si (KR); Min Hee Lee, Gunpo-si (KR)

(21) Appl. No.: 14/367,482

(22) PCT Filed: Dec. 14, 2012
(86) PCT No.: PCT/KR2012/010917

§ 371 Date: Sep. 4, 2014

(30) Foreign Application Priority Data
Dec. 28, 2011 (KR) 10-2011-0144915

(51) Int. Cl. H05K 1/02; G06F 3/045; G06F 3/0354

(52) U.S. Cl. CPC H05K 1/0274; G06F 3/03547; G06F 3/045; H05K 2201/0317; H05K 2201/0326
USPC 345/174; 428/212

(57) ABSTRACT

A transparent conductive film having excellent electrical characteristics and a touch panel using the same is provided.

A transparent conductive film in accordance with the present invention comprises: a film substrate; a first conductive thin film formed on the film substrate; a second conductive thin film formed on the first conductive thin film; and a third conductive thin film formed on the second conductive thin film, wherein the second conductive thin film is formed with a material of higher conductivity than the first conductive thin film and the third conductive thin film.

### TECHNICAL FIELD

The present invention relates to a transparent conductive film, more particularly a transparent conductive film having excellent electrical characteristics and a touch panel using the same.

### BACKGROUND ART

The most widely used transparent electrode film, which is the most important component when manufacturing touch panels, until now is an indium tin oxide (ITO) film with a total optical transmittance of 85% or over and a surface resistance of 400 Ω/square or below. A common transparent electrode film is manufactured by forming an undercoat layer on a film substrate such as a transparent polymer film and then laminating a transparent conductive thin film on an under coat.

As usage of touch panels of capacitor overlay methods or resistive methods are increasing lately, realizing low resistance with a surface resistance of less than 200 Ω/square to detect minute constant currents and minute touches are in demand. But, there are limits to a range that conductivity may have in the case of transparent electrode films using ITO thin films.

### DISCLOSURE

### Technical Problem

One objective of the present invention is to provide a transparent conductive film having excellent electrical characteristics.

Also, another objective of the present invention is to provide a touch panel using a transparent conductive film having excellent electrical characteristics.

### Technical Solution

A transparent conductive film in accordance with an embodiment of the present invention to achieve one objective above comprises: a film substrate; a first conductive thin film formed on the film substrate; a second conductive thin film formed on the first conductive thin film; and a third conductive thin film formed on the second conductive thin film, wherein the second conductive thin film is formed with a material of higher conductivity than the first conductive thin film and the third conductive thin film.

A touch panel in accordance with an embodiment of the present invention to achieve another objective above comprises: a first panel having a first transparent conductive film; a second panel opposing the first panel, and having a second transparent conductive film perpendicular to the first transparent conductive film; and a spacer placed between the first transparent conductive film and the second transparent conductive film, and the first transparent conductive film or the second transparent conductive film comprises, a film substrate, a first conductive thin film formed on the film substrate, a second conductive thin film formed on the first conductive thin film, and a third conductive thin film formed on the second conductive thin film, and the second conductive thin film is a transparent conductive film formed with a material of higher conductivity than the first conductive thin film and the third conductive thin film.

### Advantageous Effects

A transparent conductive film in accordance with the present invention, by forming a second conductive thin film, which is formed between a first conductive thin film and a second conductive thin film, with a material of higher conductivity than a first conductive thin film or a third conductive thin film, has advantages of being able to improve electrical characteristics.

Also, a transparent conductive film in accordance with the present invention, when a second first conductive thin film is formed between a first conductive thin film and a third conductive thin film comprised by an ITO material, may be expected to have effects of reducing consumption of rare metals such as indium.

Also, a touch panel in accordance with the present invention, by using a transparent conductive film with excellent electrical characteristics, may improve electrical characteristics of a touch panel.

### DESCRIPTION OF DRAWINGS

FIG. 1 is a cross-sectional drawing illustrating a transparent conductive film in accordance with an embodiment of the present invention.

FIG. 2 is a cross-sectional drawing illustrating a touch panel in accordance with embodiment 1 using a transparent conductive film of FIG. 1.

FIG. 3 is a cross-sectional drawing illustrating a touch panel in accordance with embodiment 2 using a transparent conductive film of FIG. 1.

FIG. 4 is a cross-sectional drawing illustrating a touch panel in accordance with embodiment 3 using a transparent conductive film of FIG. 1.

### BEST MODE

Advantages and features of the present invention, and method for achieving thereof will be apparent with reference to the accompanying figures and detailed description that follows. But, it should be understood that the present invention is not limited to the following embodiments and may be embodied in different ways, and that the embodiments are given to provide complete disclosure of the invention and to provide thorough understanding of the invention to those skilled in the art, and the scope of the invention is limited only by the accompanying claims and equivalents thereof. Like components will be denoted by like reference numerals throughout the specification.

Hereinafter, a transparent conductive film having excellent electrical characteristics and a touch panel using the same in accordance with the present invention will be described in detail in reference with accompanying drawings.

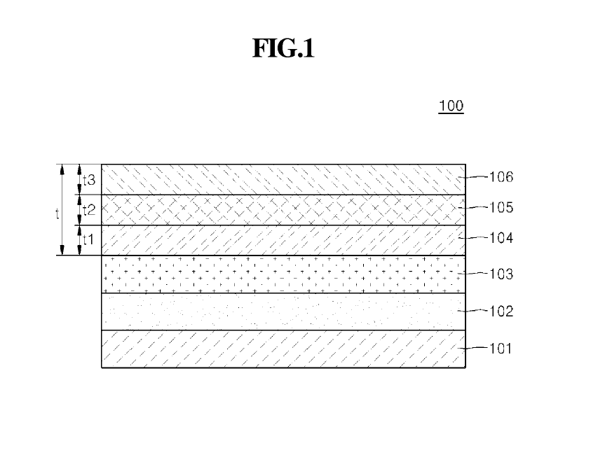

FIG. 1 is a cross-sectional drawing illustrating a transparent conductive film in accordance with an embodiment of the present invention.

Referring to FIG. 1, a transparent conductive film (100) in accordance with an embodiment of the present invention comprises a film substrate (101), and laminating on a film substrate (101) in sequence, a first dielectric thin film (102), a second dielectric thin film (103), a first conductive thin film (104), a second conductive thin film (105), and a third conductive thin film (106).

The film substrate (101) provides a formation surface of the first dielectric thin film (102) or the first conductive thin film (104), and is to provide mechanical strength to the transparent conductive film (100), and may be a substrate having transparency such as glass or transparent polymer films. For example, a plastic film selected from the group comprising polyacrylic, polyurethane, polyester, polyepoxy, polyolefin, polycarbonate, cellulose, etc. may be used for the transparent polymer film.

The film substrate (100) comprised by a transparent polymer film, to satisfy surface flatness and thermal resistance, may use the transparent polymer film which is primer coated and then hard coated.

The thickness of a film substrate (101) of about 20 μm to 1000 μm is preferable considering mechanical strength, etc. When the thickness of a film substrate (101) is less than 20 μm, mechanical strength is lacking, and there are cases where the operation of continuously forming the first and the second dielectric film (102, 103) and the first to the third conductive thin film (104, 105, 106) is difficult. On the contrary, when the thickness of the film substrate (101) is more than 20 μm, when applied to a touch panel, etc., touch characteristics, etc. are inferior, and there are problems of transmittance degrading.

The first dielectric thin film (102) and the second dielectric thin film (103) is a lower thin film of the first to the third conductive thin film (104, 105, 106), and may be formed to improve characteristics of transparency, scratch resistance, flexure resistance, durability, etc. of the transparent conductive film (100).

For example, the first dielectric thin film (102) and the second dielectric thin film (103) is made from an inorganic material [number in ( ) shows reflective index] such as NaF(1.3), Na3AlF6(1.35), LiF(1.36), MgF2(1.38), CaF2(1.4), BaF2(1.3), BaF2(1.3), SiO2(1.46), LaF3(1.55), CeF(1.63), Al2O3(1.63), etc., but may be formed with an organic material with reflective index of light of 1.4˜1.6 such as acrylic resin, urethane resin, melamine resin, alkyd resin, siloxane resin, etc., or a mixture of the inorganic material and the organic material.

For a material for the first dielectric thin film (103) among materials described above, an inorganic material and a mixture of an inorganic material and an organic material are preferable. Especially, MgF₂, Al₂O₃, etc. may be preferably used for an inorganic material. The first dielectric thin film (102) may be formed with the thickness of 10 nm to 25 nm, and preferably 13 nm to 20 nm. The second dielectric thin film (103) may be formed with the thickness of 15 nm to 100 nm, and preferably 20 nm to 60 nm. It is easy to obtain the characteristics such as transparency, scratch resistance, flexure resistance, etc. along with one another by having each of the thicknesses of the first and the second dielectric thin film (102, 103) to be in the described range. The first dielectric thin film (102) and the second dielectric thin film (103) may be formed by a vacuum evaporation method, a sputtering method, an ion plating method, a coating method, etc.

The transparent conductive film (100) described above, by laminating a lower thin film such as the first dielectric thin film and the second dielectric thin film (102, 103), in addition to improving transparency and scratch resistance or flexure resistance, a favorable result in improving touch characteristics for touch panel usage is obtained.

But, the first and the second dielectric thin film (102, 103) are not always required to be formed, and may be skipped.

The first conductive thin film (104) and the third conductive thin film (106) may be formed by common materials such as a metal such as gold (Au), silver (Ag), platinum (Pt), palladium (Pd), copper (Cu), etc., a metal oxide such as titanium oxide (TiO2), cadmium oxide (CdO), etc., a metal halides such as copper iodide, and a transparent conductive oxide such as indium tin oxide (ITO), fluorine doped tin oxide (FTO). The first conductive thin film (104) and the third conductive thin film (106) may be formed by comprising one or two or more materials selected from these. In this instance, forming the first conductive thin film (104) and the third conductive thin film (106) with an identical material is preferable to minimize changes in optical characteristics according to changes in refractive index.

Also, it is preferable to form the first conductive thin film (104) and the third conductive thin film (106), to improve optical transmittance and electrical characteristics, with an ITO material with optical transmittance of 85% and over, and the surface resistance of 400 Ω/square and below.

In this instance, the third conductive thin film (106) takes a role of compensating light reflecting from the second conductive thin film (105).

The second conductive thin film (105) is for improving electrical characteristics of a transparent conductive film (100), and is formed with a material with higher conductivity than one or more of the first conductive thin film (104) and the third conductive thin film (106).

For example, the second conductive thin film (105) may be formed by comprising one or more materials from tin (Sn), aluminum (Al), molybdenum (Mo), graphene, zinc (Zn), etc. This second conductive thin film (105), to reduce influence corresponding to optical characteristics to a minimum, may be formed with the thickness (t2) of 1 nm to 10 nm. When the thickness of the second conductive thin film (105) is below 1 nm, improving electrical characteristics to a target value with respect to the transparent conductive film (100) may not be expected. On the contrary, when the thickness of the second conductive thin film (105) is over 10 nm, optical characteristics of the transparent conductive film (100) may be reduced due to decrease in transparency. Preferably, to optimize transmittance and electrical characteristics of the transparent conductive film (100), the second conductive thin film (105) may be formed with the thickness of 5 nm.

When defining the thickness of the first conductive thin film (104) as t1, the thickness of the second conductive thin film (105) as t2, the thickness of the third conductive thin film (106) as t3, and the sum of these thicknesses (t1+t2+t3) as t, t may be formed 20 nm to 100 nm for the transparent conductive film (100). When t is below 100 nm, electrical characteristics of the transparent conductive film (100) may not be expected. On the contrary, when t is above 100 nm, the optical characteristics of the transparent conductive film (100) may be reduced due to decrease in transparency

The first to the third conductive thin film (104, 105, 106) may be formed by a common forming method for the conductive thin film well known in the art, for example, a vacuum evaporation method, a sputtering method, an ion plating method, a spray pyrolysis method, a chemical plating method, a electro plating method, a wet coating method, or using the combination of these. From these, especially, it is preferable to use a vacuum evaporation method, a sputtering method, and a wet coating method when considering forming speed, productivity, etc. of conductive thin films. The transparent conductive film (100) of these structures may have insignificant influence of optical characteristics from metallic material, but electrical characteristics in a thin film may be further improved by forming the second conductive thin film (105) between the first conductive thin film (104) and the third conductive thin film (106) and having a material with a higher conductivity than any one of these. Also, when at least any one of the first conductive thin film (104) or the third conductive thin film (106) is a transparent conductive film (100) comprised from an ITO material, effect of reducing consumption of rare metal such as indium may be expected by inserting the second conductive thin film (105) of a metal material between the first conductive thin film (104) and the third conductive thin film (106).

Meanwhile, the transparent conductive film (100) of the present invention may be preferably applied to a touch panel, especially to a resistive film method touch panel.

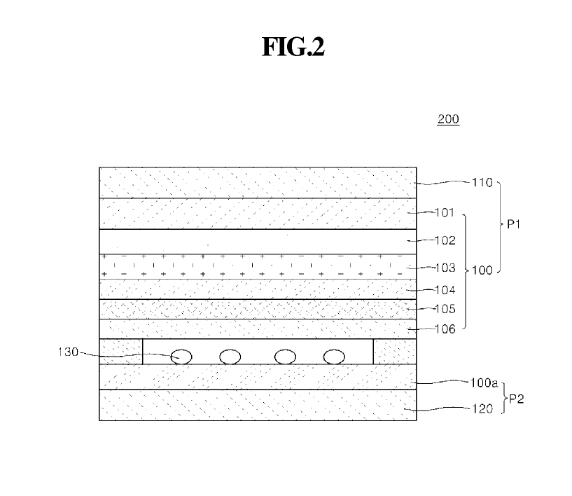

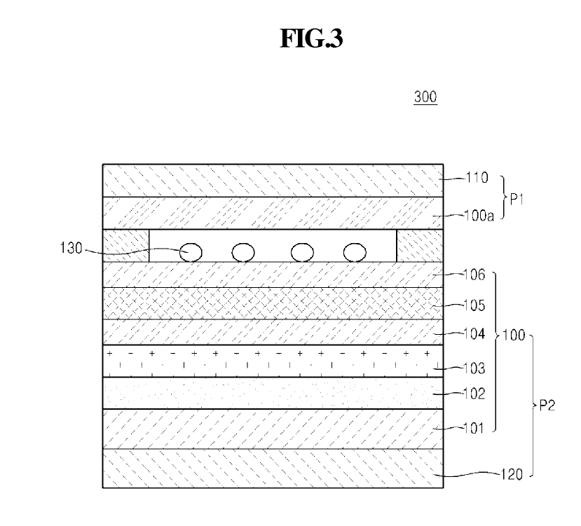

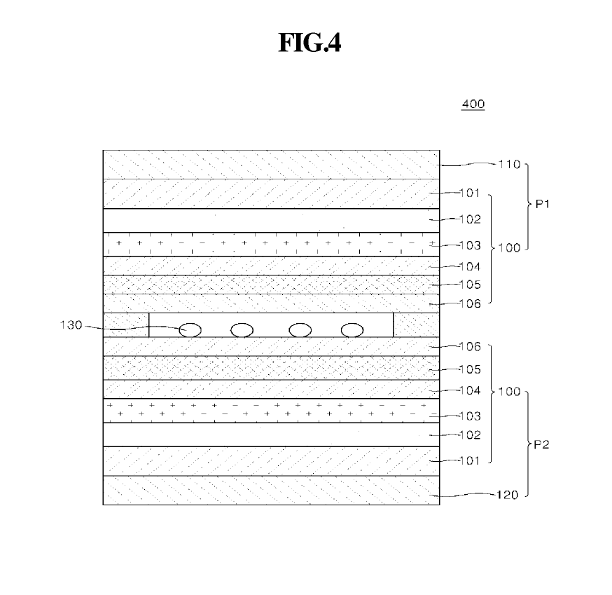

FIG. 2 is a cross-sectional drawing illustrating a touch panel in accordance with embodiment 1 using the transparent conductive film of FIG. 1, FIG. 3 is a cross-sectional drawing illustrating a touch panel in accordance with embodiment 2 using the transparent conductive film of FIG. 1, and FIG. 4 is a cross-sectional drawing illustrating a touch panel in accordance with embodiment 3 using the transparent conductive film of FIG. 1. For convenience of description, the transparent conductive film of FIG. 1 is mentioned mixed with the first transparent conductive film.

Referring to FIG. 2, the touch panel (200) comprises a first panel (P1) having a first transparent conductive film (100), a second panel (P2) opposing the first panel (P1) and having a second transparent conductive film (100a), and a spacer placed between these two first and second transparent conductive films (100, 100a).

The first transparent conductive film (100) may be adhered to the first transparent substrate (110) by an adhesive layer (not illustrated). The second transparent conductive film (100a) may be formed on the second transparent substrate (120).

The first transparent conductive film (100) and the second transparent conductive film (100a) are perpendicular to each other, and may be formed as a line type. The first and the second transparent substrate (110, 120) may be formed by a material such as plastic films, glass, etc. The second transparent conductive film (100a) may be a common transparent conductive film.

That is, a touch panel (200) is comprised by opposite layout of a pair of the first and the second panels (P1, P2) having the first and the second transparent conductive film (100, 100a), and a spacer (130) is put in between the first and the second transparent conductive film (100, 100a) formed perpendicular to each other to oppose each other.

The touch panel (200) uses the transparent conductive film (100) of FIG. 1 on the first panel (P1), which is on the top side where pressure is applied. The touch panel (200) functions as a transparent switch having a plane body, turning on in a electrical circuitry by making current flow through the first and the second transparent conductive film (100, 100a) when coming in contact each other by the pressure being applied to the first panel (P1) when touched with a finger, pen, etc., and turning off back to the original off state when the pressure is removed. In this instance, the touch panel (200) with much improved electrical characteristics may be realized because the first panel (100) applies a transparent conductive film (100) with excellent electrical characteristics of the present invention. Meanwhile, the touch panel (200) in FIG. 2 applies the transparent conductive film (100) of the present invention in only the top first panel (P1), but is not limited to this.

On the other hand, as illustrated in FIG. 3, the touch panel (300) may apply the transparent conductive film (100) of the present invention only in the bottom second panel (P2). Also, as illustrated in FIG. 4, the touch panel may apply the transparent conductive film (100) of the present invention in all of the top first panel (P1) and the bottom second panel (P2). Excluding this, since the remainder contents of FIG. 3 and FIG. 4 may be identical to FIG. 2, duplicate contents are skipped.

Touch panels (200, 300, 400) in accordance with embodiments 1 to 3 may be equipped in display devices such as Liquid Crystal Display (LCD), Plasma Display Panel (PDP), Light Emitting Diode (LED), Organic Light Emitting Diodes (OLED), or E-Paper.

Hereinafter, examples of the present invention is presented by comparing with comparative examples, and described in further detail.

Electrical characteristics of a transparent conductive film was evaluated by measuring carrier concentration, mobility, and resistance before and after heat treatment. Also, optical characteristics of a transparent conductive film was evaluated by measuring transmittance, reflectivity, etc.

### EXAMPLE 1

A transparent conductive film specimen was manufactured by forming a bottom ITO thin film with a thickness of 10 nm, a Sn thin film with a thickness of 5 nm, and a top ITO thin film with a thickness of 10 nm was formed in order by using a DC sputtering method on one side of a transparent film substrate comprised by polyethylene terephthalate film (referred to as PET film below). And then, a transparent conductive film specimen was heat treated for 60 minutes in a temperature of 150° C.

### EXAMPLE 2

Except for forming, from top, ITO thin film with a thickness of 20 nm, a Sn thin film with a thickness of 5 nm, and an ITO thin film with a thickness of 20 nm, other configurations are identical to example 1.

### EXAMPLE 3

Except for forming, from top, ITO thin film with a thickness of 10 nm, a Sn thin film with a thickness of 10 nm, and an ITO thin film with a thickness of 10 nm, other configurations are identical to example 1.

### EXAMPLE 4

Except for forming, from top, Au thin film with a thickness of 10 nm, a Sn thin film with a thickness of 10 nm, and an Au thin film with a thickness of 10 nm, other configurations are identical to example 1.

### EXAMPLE 5

Except for forming, from top, Au thin film with a thickness of 20 nm, a graphene thin film with a thickness of 5 nm, and an Cu thin film with a thickness of 20 nm, other configurations are identical to example 1.

### COMPARATIVE EXAMPLE 1

Except for forming a bottom ITO thin film with a thickness of 20 nm, and not forming a Sn thin film and a top ITO thin film, it is identical to example 1.

### COMPARATIVE EXAMPLE 2

Except for forming a bottom ITO thin film with a thickness of 15 nm, and not forming a top ITO thin film, it is identical to example 1.

### COMPARATIVE EXAMPLE 2

Except for forming a bottom ITO thin film with a thickness of 20 nm, and not forming a top ITO thin film, it is identical to example 1.

<Electrical Characteristics Evaluation of a Transparent Conductive Film>

Table 1 illustrates the results of electrical characteristics of a transparent conductive film in accordance with examples 1˜5 and comparative examples 1˜3.

TABLE 1

| | Carrier concentration(cm⁻⁵) | | Mobility(cm²/V · s) | | Resistance (cm · Ω) | |
|---|---|---|---|---|---|---|
| | Before heat | After heat | Before heat | After heat | Before heat | After heat |
| | treatment | treatment | treatment | treatment | treatment | treatment |
| Example 1 | 4.32 × 10²⁰ | 4.37 × 10²⁰ | 1.52 × 10¹ | 2.12 × 10¹ | 9.50 × 10⁻⁴ | 6.80 × 10⁻⁴ |
| Example 2 | 4.11 × 10²⁰ | 4.21 × 10²⁰ | 1.36 × 10¹ | 1.12 × 10¹ | 8.73 × 10⁻⁴ | 6.15 × 10⁻⁴ |
| Example 3 | 3.45 × 10²¹ | 3.49 × 10²¹ | 4.52 × 10² | 5.34 × 10² | 3.23 × 10⁻⁵ | 2.72 × 10⁻⁵ |
| Example 4 | 1.25 × 10²² | 2.34 × 10²² | 9.52 × 10¹ | 1.02 × 10² | 2.56 × 10⁻⁵ | 1.78 × 10⁻⁵ |
| Example 5 | 4.25 × 10²¹ | 2.20 × 10²¹ | 5.39 × 10¹ | 3.29 × 10¹ | 4.12 × 10⁻⁴ | 1.86 × 10⁻⁴ |
| Comparative | 3.17 × 10²⁰ | 9.90 × 10¹⁹ | 1.90 × 10¹ | 3.46 × 10¹ | 1.04 × 10⁻⁵ | 1.82 × 10⁻⁵ |
| example 1 | | | | | | |
| Comparative | 1.42 × 10²¹ | 2.42 × 10²¹ | 8.53 × 10⁰ | 2.30 × 10⁰ | 5.18 × 10⁻⁴ | 1.13 × 10⁻⁵ |
| example 2 | | | | | | |
| Comparative | 4.25 × 10²⁰ | 1.05 × 10²⁰ | 1.86 × 10¹ | 2.45 × 10¹ | 7.90 × 10⁻⁴ | 2.44 × 10⁻⁵ |
| example 3 | | | | | | |

Referring to table 1, in case of examples 3˜4, resistance is relatively low, and in the case of examples 1˜2, 5, resistance is little higher than examples 3˜4, but resistance is lower than comparative examples 1˜3.

That is, in the case of examples 1˜5, showing excellent electrical characteristics by having lower resistance compared to comparative example 1˜3 was observed.

In the description above, resistance is a result shown from two factors of carrier concentration and mobility, and when carrier concentration is high, and mobility is high, resistance decreases.

Also, through examples 1˜3, it is observed that resistance is inverse proportional to thickness of Sn thin film, and is proportional to thickness of each ITO thin films. Therefore, it is concluded that excellent electrical characteristics may be shown through improvements in electrical conductivity when a thick Sn thin film is inserted in between relatively thin ITO thin films.

Also, through examples 4˜5, it was observed that configuring layers with only metal, or configuring layers by inserting graphene in between metal and metal, also shows excellent electrical characteristics.

<Optical Characteristics Evaluation of Transparent Conductive Film>

Table 2 illustrates the results of optical characteristics of a transparent conductive film in accordance with examples 1˜5 and comparative examples 1˜3.

TABLE 2

| | | Example | Example | Example | Example | Example | Comparative | Comparative | Comparative |
|---|---|---|---|---|---|---|---|---|---|
| Optical characteristics | | 1 | 2 | 3 | 4 | 5 | example 1 | example 2 | example 3 |
| Transmittance | T % | 83.33 | 82.12 | 78.86 | 62.84 | 58.67 | 89.02 | 19.97 | 54.92 |
| | (@550 m) | | | | | | | | |
| | Y(D65) | 83.38 | 81.28 | 79.98 | 54.17 | 43.29 | 88.69 | 20.53 | 55.45 |
| | b* | 4.74 | 4.52 | 6.24 | 6.17 | 11.27 | 2.81 | 6.80 | 7.73 |
| | Haze | 1.47 | 1.51 | 3.21 | 5.29 | 7.65 | 0.72 | 2.78 | 0.79 |
| Reflectivity | R % | 14.85 | 13.58 | 20.23 | 35.52 | 39.65 | 11.57 | 49.77 | 13.22 |
| | (@550 m) | | | | | | | | |
| | Y(D65) | 14.80 | 13.26 | 21.85 | 37.1 | 48.22 | 11.79 | 49.31 | 12.91 |
| | b* | −7.37 | −6.73 | −0.34 | −12.47 | −14.33 | −6.94 | −0.24 | 6.84 |

Here, T is an optical transmittance at 550 nm wavelength, T(D65) is an entire transmittance or an entire reflectivity, b* is amount of yellowish, Haze is turbidity, R is optical reflectivity at 550 nm wavelength.

Referring to table 2, transmittance in examples 1˜2 and comparative example 1 is relatively high, whereas comparative example 2 was very low, and examples 3˜5 and comparative example 3 shows little lower results compared to examples 1˜2.

Also, b* value is lowest in comparative example 1, examples 1˜2 was little lower compared to examples 3˜4 and comparative examples 2˜3, and example 5 showed the highest result.

Also, turbidity in comparative examples 1, 3 is relatively low, whereas is relatively high in examples 4˜5, and showed a value relatively in between in examples 1˜3 and comparative example 2.

Also, reflectivity is relatively high in examples 4˜5 and comparative example 2, whereas is relatively low in examples 1˜3 and comparative examples 1, 3.

Through this, it was observed that examples 1˜3 and comparative example 1 is a preferred condition of optical characteristics required for transparent conductive film of the present invention.

Putting together the experimental results above, it was observed that examples 1˜3 shows excellent characteristics in all of electrical and optical aspects. It was observed that examples 4˜5 have excellent electrical characteristics, but optical characteristics are relatively low.

Also, it was observed that comparative example 1 has the most excellent optical characteristics but electrical characteristics are very low, and comparative examples 2˜3 has very lower optical and electrical aspects, especially optical aspects.

Although embodiments in accordance with the present invention have been described herein, various modifications and variations can be made by those skilled in the arts. And it should be understood that these modifications and variations are within the scope of the present invention if it is not outside the boundary of the technical concept of the present invention. Therefore, the scope of the present invention should be defined by the appended claims.

1. A transparent conductive film comprising:
a film substrate;
a first conductive thin film formed on the film substrate;
a second conductive thin film formed on the first conductive thin film; and
a third conductive thin film formed on the second conductive thin film,
wherein the second conductive thin film formed with a material with higher conductivity than the first conductive thin film or the third conductive thin film.

2. A transparent conductive film according to claim 1, wherein the second conductive thin film comprises one or more materials selected from tin (Sn), aluminum (Al), molybdenum (Mo), graphene, and zinc (Zn).

3. A transparent conductive film according to claim 1, wherein the second conductive thin film is formed with a thickness of 1 nm to 10 nm.

4. A transparent conductive film according to claim 1, wherein the first conductive thin film and the third conductive thin film comprises one or more materials selected from gold (Au), silver (Ag), platinum (Pt), palladium (Pd), copper (Cu), titanium oxide (TiO2), cadmium oxide (CdO), and copper iodide (CuI).

5. A transparent conductive film according to claim 1, wherein the first conductive thin film and the third conductive thin film is formed from a transparent conductive oxide, and the transparent conductive oxide is an indium tin oxide (ITO) or a fluorine doped tin oxide (FTO).

6. A transparent conductive film according to claim 1, wherein the first conductive thin film is formed with an identical material as the third conductive thin film.

7. A transparent conductive film according to claim 1, wherein a sum of thicknesses of the first conductive thin film, the second conductive thin film, and the third conductive thin film is 20 nm to 100 nm.

8. A transparent conductive film according to claim 1, further comprising:
between the film substrate and the first conductive thin film,
a first dielectric thin film in contact with the film substrate; and
a second dielectric thin film formed on the first dielectric thin film.

9. A transparent conductive film according to claim 8, wherein the first dielectric thin film and the second dielectric thin film includes one or more elements selected from inorganic materials and organic materials.

10. A touch panel comprising:
a first panel having a first transparent conductive film;
a second panel opposing the first panel, and having a second transparent conductive film perpendicular to the first transparent conductive film; and
a spacer placed between the first transparent conductive film and the second transparent conductive film,
and the first transparent conductive film or the second transparent conductive film comprises, a film substrate, a first conductive thin film formed on the film substrate, a second conductive thin film formed on the first conductive thin film, and a third conductive thin film formed on the second conductive thin film, and the second conductive thin film is a transparent conductive film formed with a material of higher conductivity than the first conductive thin film and the third conductive thin film.
